(19) United States
(12) Patent Application Publication
(10) Pub. No.: US 2010/0033260 A1
(43) Pub. Date: Feb. 11, 2010

(54) OSCILLATION CIRCUIT

(75) Inventor: Makoto SAKAGUCHI, Ohtsu-shi (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/511,616

(22) Filed: Jul. 29, 2009

(30) Foreign Application Priority Data
Aug. 6, 2008 (JP) 2008-202590

(51) Int. Cl. H03L 7/099

(52) U.S. Cl. 331/36 C

(57) ABSTRACT

An oscillation circuit according to an exemplary embodiment of the present invention includes: a power supply voltage terminal applied with a power supply voltage; a feedback loop circuit that outputs an oscillation frequency signal; and a correction circuit that corrects a time constant of the feedback loop circuit in accordance with the power supply voltage applied to the power supply voltage terminal. The configuration facilitates the correction of an oscillation frequency that varies depending on the fluctuation of the power supply voltage.

### BACKGROUND

1. Field of the Invention

The present invention relates to an oscillation circuit, and more particularly, to a technique for correcting an oscillation frequency.

2. Description of Related Art

In recent years, there has been a demand for a reduction in consumption current in booster circuits for use in portable electronic devices such as cellular phones. To satisfy the demand, there has been proposed a method for reducing an oscillation frequency of an oscillation circuit provided in each booster circuit. Variation of the oscillation frequency, however, causes a problem of deterioration in capability of the booster circuit. Accordingly, in order to reduce the consumption current without reducing the capability of the booster circuit, it is necessary to stabilize the oscillation frequency.

A solution for this problem is proposed in Japanese Unexamined Patent Application Publication No. 2006-165512. FIG. 5 shows an oscillation circuit disclosed in Japanese Unexamined Patent Application Publication No. 2006-165512. The circuit shown in FIG. 5 includes a power supply voltage terminal VDD, a ground voltage terminal GND, an oscillation output terminal OSCout, a first-stage inverter circuit I1, a second-stage inverter circuit I2, a third-stage inverter circuit I3, a resistor element R1, and a capacitor element C1. Note that the reference symbols “VDD”, “GND”, “R1”, and “C1” represent terminal names, and also represent a power supply voltage, a ground voltage, a resistance value, and a capacitance value, respectively, for convenience.

A signal output from the inverter circuit I1 is input to the input terminal of the inverter circuit I2. A signal output from the inverter circuit I2 is input to each of the input terminal of the inverter circuit I3 and one terminal of the capacitor element C1. A signal output from the inverter circuit I3 is input to one terminal of the resistor element R1. A signal output from the inverter circuit I3 is supplied to the oscillation output terminal OSCout. In other words, the signal output from the inverter circuit I3 is used as an output signal of the oscillation output terminal OSCout. A signal output from the other terminal of the resistor element R1 is input to each of the other terminal of the capacitor element C1 and the input terminal of the inverter circuit I1. Note that a high-potential side power supply terminal of each of the inverter circuits I1, I2, and I3 is connected to the power supply voltage terminal VDD. Further, a low-potential side power supply terminal of each of the inverter circuits I1, I2, and I3 is connected to the ground voltage terminal GND.

The circuit configuration employed for the inverter circuits I1, I2, and I3 is generally known as a ring oscillator. Thus, when the power supply voltage VDD is applied to the circuit shown in FIG. 5, the circuit starts oscillation. In this case, an oscillation frequency is determined mainly based on the resistance value R1, the capacitance value C1, and a driving capability of each of the inverter circuits I1, I2, and I3. Note that an on-resistance value of each of transistors constituting the inverters is calculated based on the driving capability of each of the inverter circuits I1, I2, and I3.

It is generally known that the oscillation frequency is proportional to the reciprocal of a value (time constant) obtained by multiplying a sum of the resistance value R1 and each of the on-resistance values of the transistors constituting the inverter circuits I1, I2, and I3 by the capacitance value C1. For example, when the power supply voltage VDD drops, the driving capability of each of the inverter circuits I1, I2, and I3 decreases (i e. on-resistance increases) as shown in the example shown in FIG. 6A. As a result, the time constant increases as shown in FIG. 6B. Further, the oscillation frequency decreases as shown in FIG. 6C.

In this manner, when the power supply voltage VDD fluctuates due to some cause, the driving capability of each of the inverter circuits I1, I2, and I3 varies, which causes a problem that the oscillation frequency becomes unstable.

The related art disclosed in Japanese Unexamined Patent Application Publication No. 2006-165512 makes it possible to adjust process characteristics of the resistor element R1 and the capacitor element C1 in the circuit shown in FIG. 5. Thus, it is possible to adjust the rate of change of each of the resistance value R1 and the capacitance value C1 that vary depending on the fluctuation of the power supply voltage VDD. In other words, an increase in oscillation frequency due to an increase in the power supply voltage VDD can be suppressed.

For example, a description is given of a case where the oscillation frequency increases with the increase of the power supply voltage VDD. In this case, the following countermeasure is taken, for example. That is, the time constant is increased by adjustment of the process characteristics so that the capacitance value C1 increases with the increase of the power supply voltage VDD, to thereby stabilize the oscillation frequency.

### SUMMARY

The present inventor has found a problem that the process characteristics of the resistor element R1 and the capacitor element C1 need to be adjusted in the related art, in order to stabilize the oscillation frequency that varies depending on the power supply voltage. The adjustment of the process characteristics is extremely complicated, which causes a problem of an increase in man-hour for development and costs.

A first exemplary aspect of an embodiment of the present invention is an oscillation circuit including a power supply voltage terminal applied with a power supply voltage; a feedback loop circuit that outputs an oscillation frequency signal; and a correction circuit (e.g., a correction circuit 100 according to a first exemplary embodiment of the invention) that corrects a time constant of the feedback loop circuit in accordance with the power supply voltage applied to the power supply voltage terminal.

The circuit having the configuration described above facilitates the correction of an oscillation frequency that varies depending on the fluctuation of the power supply voltage.

According to an exemplary embodiment of the present invention, it is possible to provide an oscillation circuit that facilitates the correction of an oscillation frequency that varies depending on the fluctuation of the power supply voltage.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 shows an oscillation circuit according to a first exemplary embodiment of the present invention;

FIG. 2A is a graph showing an example of a variation in oscillation frequency when a power supply voltage fluctuates in the oscillation circuit according to the first exemplary embodiment of the present invention;

FIG. 2B is a graph showing an example of a variation in oscillation frequency when the power supply voltage fluctuates in the oscillation circuit according to the first exemplary embodiment of the present invention;

FIG. 2C is a graph showing an example of a variation in oscillation frequency when the power supply voltage fluctuates in the oscillation circuit according to the first exemplary embodiment of the present invention;

FIG. 3 shows an oscillation circuit according to a second exemplary embodiment of the present invention;

FIG. 4 shows an example of an inverter circuit;

FIG. 5 shows an oscillation circuit of the related art;

FIG. 6A is a graph showing an example of a variation in oscillation frequency when a power supply voltage fluctuates in the oscillation circuit of the related art;

FIG. 6B is a graph showing an example of a variation in oscillation frequency when the power supply voltage fluctuates in the oscillation circuit of the related art; and

FIG. 6C is a graph showing an example of a variation in oscillation frequency when the power supply voltage fluctuates in the oscillation circuit of the related art.

### DETAILED DESCRIPTION OF THE EXEMPLARY EMBODIMENTS

Exemplary embodiments to which the present invention is applied will be described in detail below with reference to the accompanying drawings A redundant explanation is omitted as appropriate for clarification of the explanation.

### First Exemplary Embodiment

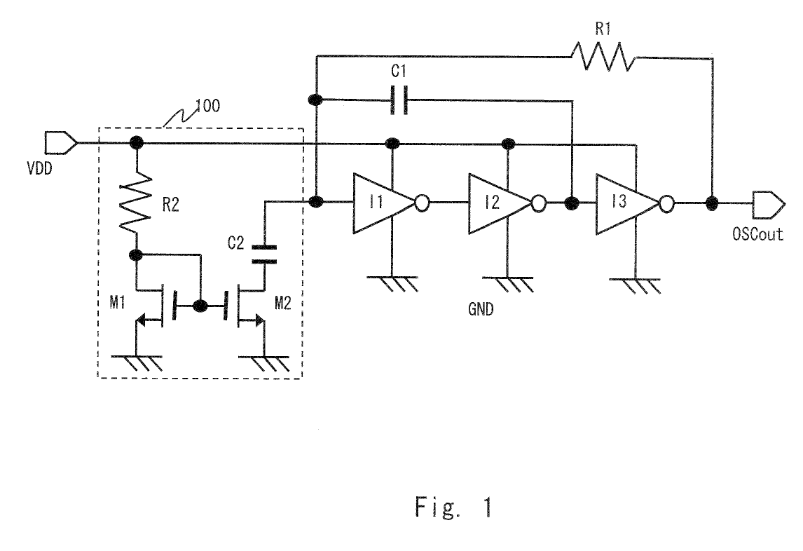

Referring first to FIG. 1, the configuration of an oscillation circuit according to a first exemplary embodiment of the present invention will be described. The circuit shown in FIG. 1 includes the circuit of the related art shown in FIG. 5 as well as a correction circuit 100. The circuit shown in FIG. 1 serves as a feedback loop circuit that includes an inverter circuit I1, an inverter circuit I2, an inverter circuit I3, a resistor element R1, and a capacitor element C1. Further, the correction circuit 100 includes a resistor element R2, an Nch FET (first transistor) M1, an Nch FET (second transistor) M2, and a capacitor element C2. In this configuration, the circuit shown in FIG. 1 has a function of correcting a time constant of a feedback loop circuit of the oscillation circuit in accordance with the fluctuation of a power supply voltage VDD. The resistor element R2 and the FETs M1 and M2 constitute a control circuit. The control circuit has a function of controlling a resistance value of the FET M2 in accordance with the fluctuation of the power supply voltage VDD. Note that the reference symbols “R2” and “C2” represent terminal names, and also represent a resistance value and a capacitance value, respectively, for convenience.

First, the output terminal of the inverter circuit I1 is connected to the input terminal of the inverter circuit I2. The output terminal of the inverter circuit I2 is connected to each of the input terminal of the inverter circuit I3 and one terminal of the capacitor element C1. The output terminal of the inverter circuit I3 is connected to one terminal of the resistor element R1. The output terminal of the inverter circuit I3 is also connected to the oscillation output terminal OSCout. The other terminal of the resistor element R1 is connected to each of the other terminal of the capacitor element C1, the input terminal of the inverter circuit I1, and one terminal of the capacitor element C2.

The power supply voltage terminal VDD is connected to one terminal of the resistor element R2. The power supply voltage terminal VDD is also connected to a high-potential side power supply terminal of each of the inverter circuits I1, I2, and I3. Note that a low-potential side power supply terminal of each of the inverter circuits I1, I2, and I3 is connected to a ground voltage terminal GND.

The other terminal of the resistor element P2 is connected to each of the drain and gate of the FET M1 and the gate of the FET M2. The other terminal of the capacitor element C2 is connected to the drain of the FET M2. Further, the source of each of the FETs M1 and M2 is connected to the ground voltage terminal GND.

Referring next to FIG. 1, operation of the oscillation circuit according to the first exemplary embodiment of the present invention will be described.

First a signal output from the inverter circuit I1 is input to the input terminal of the inverter circuit I2. A signal output from the inverter circuit I2 is input to each of the input terminal of the inverter circuit I3 and one terminal of the capacitor element C1. A signal output from the inverter circuit I3 is input to one terminal of the resistor element R1. Further, the signal output from the inverter circuit I3 is supplied to the oscillation circuit terminal OSCout. In other words, the signal output from the inverter circuit I3 is used as an output signal of the oscillation circuit terminal OSCout. A signal output from the other terminal of the resistor element R1 is input to each of the other terminal of the capacitor element C1, the input terminal of the inverter circuit I1, and one terminal of the capacitor element C2.

The inverter circuits I1, I2, and I3 constitute a ring oscillator as in the circuit of the related art. Accordingly, when the power supply voltage VDD is applied to the circuit shown in FIG. 1, the circuit starts oscillation. In this case, an oscillation frequency is determined mainly based on the resistance value R1, the capacitance value C1, and a driving capability of each of the inverter circuits I1, I2, and I3, as well as on the capacitance value C2 and a resistance component of the Nch PET M2.

As described above, one terminal of the resistor element R2 constituting the correction circuit 100 is connected to the power supply voltage terminal VDD. Further, the other terminal of the resistor element R2 is connected to each of the drain and gate of the FET M1. It is assumed herein that a value of a current flowing through the FET M1 is represented by “i1” and a drain-source voltage of the FET M1 is represented by “Vm1”. In this case, the current value i1 is proportional to the power supply voltage VDD as expressed by the following formula (1)

i1=(VDD−Vm1)/R2 (1)

The FETs M1 and M2 included in the correction circuit 100 have a current mirror circuit configurations It is assumed herein that a value of a current flowing through the FET M2 is represented by “i2” and a current mirror ratio between the FETs M1 and M2 is represented by “A”. In this case, the current value i2 is proportional to the current value i1 as expressed by the following formula (2).

i2=A·i1 (2)

The source of the FET M2 is connected to the ground voltage terminal GND. The drain of the FET M2 is connected to the other terminal of the capacitor element C2. Accordingly, no direct current flows across the drain and source of the FET M2. However, since one terminal of the capacitor element C2 is connected to the input terminal of the FET I1 constituting the oscillation circuit, the one terminal of the capacitor element C2 is influenced by an AC signal generated by the oscillation circuit. In other words, an alternating current proportional to the current value i flows across the source and drain of the FET M2.

Assuming that the resistance value of the FET M2 is represented by “Rm2”, the resistance value Rm2 is proportional to the reciprocal of the value of the power supply voltage VDD.

In this case, the frequency of the oscillation circuit shown in FIG. 1 is determined mainly based on the resistance value R1, the capacitance value C1, and the driving capability of each of the inverter circuits I1, I2, and I3, as well as on the capacitance value C2 and the resistance value Rm2. For example, when the power supply voltage VDD rises due to some cause, the resistance value Rm2 decreases. In this case, the source of the FET M2 is connected to the ground voltage terminal GND. Accordingly, as the resistance value Rm2 decreases, the amount of current extracted from the feedback loop circuit constituting the oscillation circuit increases. As a result, the time constant of the feedback loop circuit increases and the oscillation frequency decreases. In other words, an increase in oscillation frequency due to an increase in the power supply voltage VDD can be suppressed by providing the correction circuit 100.

Further, in the correction circuit 100, the size of each of the resistor element R2 and the FET M1 and the current mirror ratio between the FETs M1 and M2 are adjusted, thereby making it possible to adjust the rate of change of the resistance value Rm2 in accordance with the fluctuation of the power supply voltage VDD. Thus, the rate of change of oscillation frequency depending on the fluctuation of the power supply voltage VDD can be adjusted.

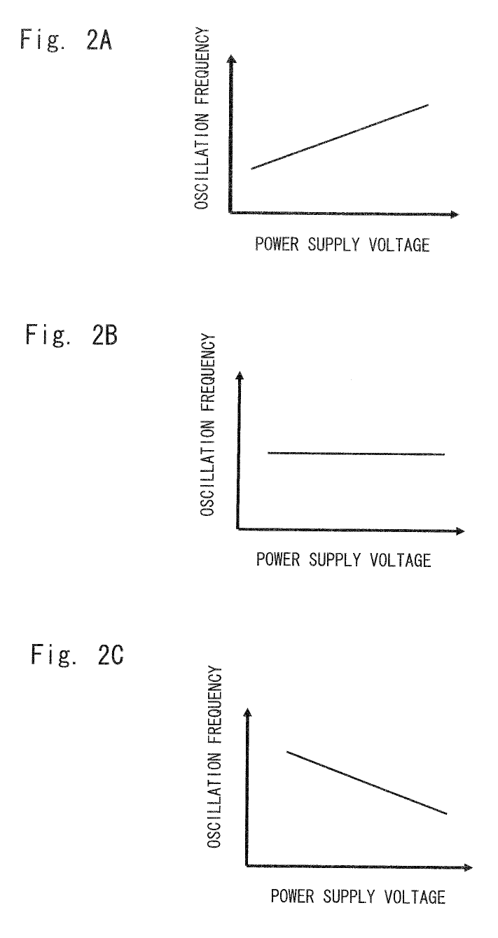

For example, when the correction amount of the correction circuit 100 is reduced (i.e., when the rate of change of the resistance value Rm2 is reduced), the oscillation frequency increases with the increase of the power supply voltage VDD as shown in FIG. 2A. Further, when the correction amount of the correction circuit 100 is increased (i.e., when the rate of change of the resistance value Rm2 is increased), the oscillation frequency decreases with the increase of the power supply voltage VDD as shown in FIG. 2c. Alternatively, the correction amount can be adjusted so as to prevent the oscillation frequency from varying, even when the power supply voltage VDD changes as shown in FIG. 2B.

Meanwhile, the consumption current of the circuit shown in FIG. 1 is mainly composed of a current flowing during a change in signals of the inverter circuits I1, I2, and I3, and of a current supplied to the capacitor element C1. The consumption current varies directly with the frequency. In other words, the increase in oscillation frequency is suppressed by using the correction circuit 100, which results in suppression of an increase in consumption current.

The size of each of the resistor element R2 and the FET M1, and the current mirror ratio between the FETs M1 and M2 can be easily adjusted. For example, in a semiconductor manufacturing process, a plurality of elements for different conditions (e.g., transistors for M1) are prepared. There, a connection state with each of the plurality of elements is switched to thereby perform the adjustment so that the oscillation circuit has a desired rate of change of the oscillation frequency depending on the fluctuation of the power supply voltage VDD. This eliminates the need for performing any complicated adjustment of process characteristics on the resistor element and the capacitor element, unlike the related art. Moreover, a plurality of oscillation circuits for different correction conditions can be formed on the same wafer.

### Second Exemplary Embodiment

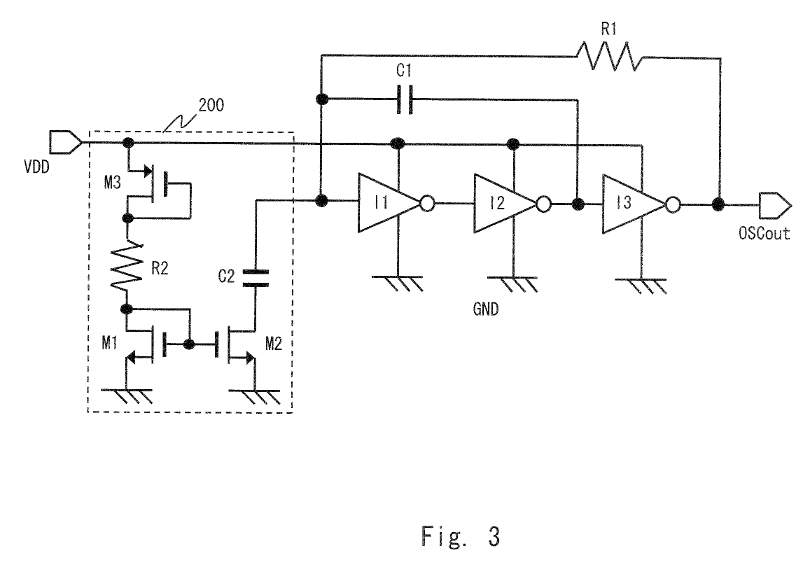

Referring now to FIG. 3, the configuration of an oscillation circuit according to a second exemplary embodiment of the present invention will be described. The circuit shown in FIG. 3 includes a correction circuit 200 in place of the correction circuit 100 constituting the circuit shown in FIG. 1. The correction circuit 200 includes the FETs M1 and M2, the resistor element R2, and the capacitor element C2, which constitute the correction circuit 100, as well as an additional circuit. The additional circuit is used to change a correction factor of the time constant with respect to the fluctuation of the power supply voltage VDD. In other words, the additional circuit is used to change the rate of change of the resistance value of the FET M2 depending on the fluctuation of the power supply voltage VDD. The additional circuit is actually composed of a Pch FET (third transistor) M3. Note that the circuit configuration of this exemplary embodiment is similar to that of the first exemplary embodiment except for the correction circuit 200, so the description thereof is omitted.

The source of the FET M3 is connected to the power supply voltage terminal VDD. The drain and gate of the FET M3 are each connected to one terminal of the resistor element R2.

It is assumed herein that a value of a current flowing through each of the FETs M1 and M3 is represented by “i1a”, and a drain-source voltage of the FET M1 is represented by “Vm1”. Additionally, a drain-source voltage of the FET M3 is represented by “Vm3”. In this case, the current value i1a can be expressed by the following formula (3).

i1a=(VDD−Vm1−Vm3)/R2 (3)

Meanwhile, in the case of the circuit including the correction circuit 100 as shown in FIG. 1, the value i1 of the current flowing through the FET M1 can be expressed by the formula (1). As is apparent from the comparison between the formulae (1) and (3), the value of the current flowing through the FET M1 in the circuit shown in FIG. 1 is different from that in the circuit shown in FIG. 3.

For example, a description is given of a case where the power supply voltage VDD is 5 V; each of the drain-source voltages Vm1 and Vm3 is 1 V; and the capacitance value R2 is 1 kΩ. In this case, the value i1 of the current flowing through the FET M1 in the circuit shown in FIG. 1 can be obtained by the following formula (4).

i1=(5−1)/1000=0.004 A→4 mA (4)

In this case, it is assumed that the power supply voltage VDD changes to 4.5 V due to some cause. That is, it is assumed that the power supply voltage VDD is reduced by 10%. In such a case, the value i1 of the current flowing through the FET M1 can be obtained by the following formula (5).

i1=(4.5−1)/1000=0.0035 A−3.5 mA (5)

Accordingly, it is obvious that when the rate of change of the power supply voltage VDD is −10%, the rate of change of the current value i1 is −12.5% Note that a voltage change due to the change in drain current of each of the drain-source voltages Vm1 and Vm3 is negligible, and thus the voltage change is not taken into consideration in this exemplary embodiment.

Meanwhile, the value i1a of the current flowing through the FET M1 in the circuit shown in FIG. 3 can be obtained by the following formula (6).

i1a=(5−1−1)/1000=0.003 A→3 mA (6)

It is assumed herein that the power supply voltage VDD changes to 4.5 V due to some cause. In this case, the value i1a of the current flowing through the FET M1 can be obtained by the following formula (7).

i1a=(4.5−1−1)/1000=0.0025 A→2.5 mA (7)

Accordingly, it is obvious that when the rate of change of the power supply voltage VDD is −10%, the rate of change of the current value i1a is −16.7%. That is, in the circuit shown in FIG. 3, the rate of change of the current value i1a depending on the fluctuation of the power supply voltage VDD can be increased.

Note that the FETs M1 and M2 included in the correction circuit 200 have a current mirror circuit configuration as in the case of the correction circuit 100. Assuming that a value of a current flowing through the FET M2 is represented by “i2a”, the value i2a of the current flowing through the FET M2 is proportional to the value i1a of the current flowing through the FET M1 as shown in the formula (2). Accordingly, in the circuit shown in FIG. 3, the rate of change of the current value i2a depending on the fluctuation of the power supply voltage VDD can be increased. This results in an increase in the rate of change of oscillation frequency depending on the fluctuation of the power supply voltage VDD in the correction circuit 200.

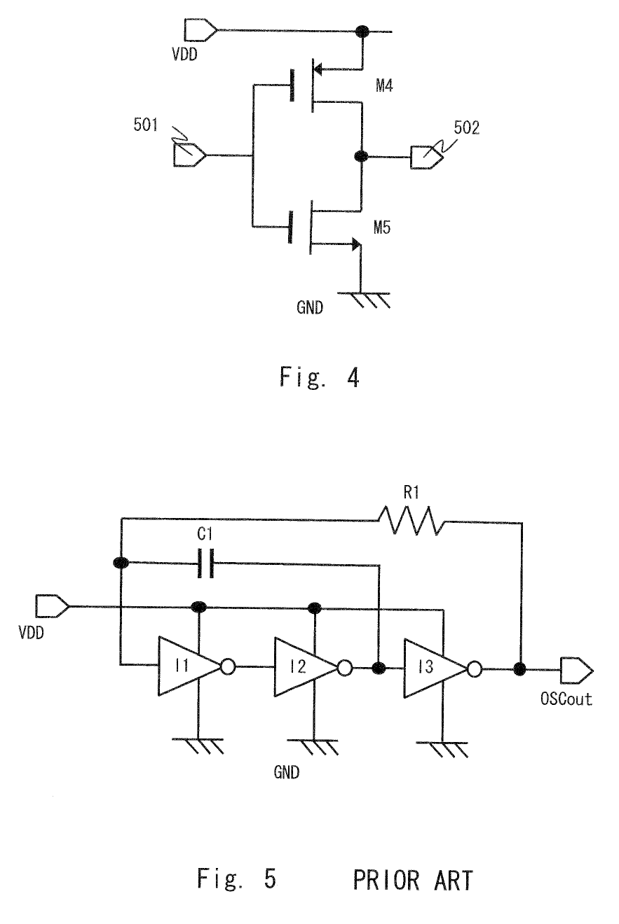

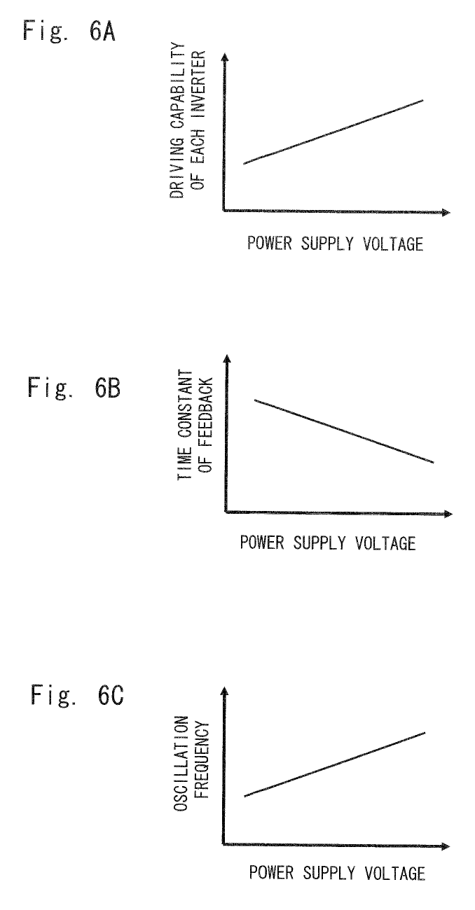

On the other hand, as shown in FIG. 4, each of the inverter circuits I1, I2, and I3 can be composed of a Pch FET M4 and an Nch FET M5. In this case, the threshold voltage of the Pch FET or the Nch FET may fluctuate due to process variations or the like. Also in this case, the oscillation circuit shown in FIG. 3 is capable of stabilizing the oscillation frequency. For example, a description is given of a case where the threshold voltage of the Pch FET increases. In the example of the inverter circuit shown in FIG. 4, a signal input terminal 501 is connected to the gate of each of the FETs M4 and M5. The source of the FET M4 is connected to the power supply voltage terminal VDD. The drain of the FET M4 is connected to each of a signal output terminal 502 and the drain of the FET M5. The source of the FET M5 is connected to the ground voltage terminal GND.

In this case, in the circuit of the related art shown in FIG. 5, as the threshold voltage of the Pch FET increases the driving capability of the inverter circuits each including the Pch FET M4 deteriorates (i.e., on-resistance increases). Thus, the time constant of the feedback loop circuit increases, and the oscillation frequency decreases. In the circuit including the correction circuit 200 as shown in FIG. 3, the threshold voltage of the Pch FET M3 also increases, which results in an increase of the drain-source voltage Vm3 of the FET M3. Further, the value i1a of the current flowing through the FET M1 decreases.

Since the FETs M1 and M2 have the current mirror circuit configuration, the value i2a of the current flowing through the FET M2 is proportional to the value i1a of the current flowing through the FET M1. Accordingly, the current value i2a also decreases with the decrease of the current value i1a. This results in suppression of a decrease in oscillation frequency.

In this manner, the variation of the oscillation frequency can be suppressed even when the threshold voltage of the Pch FET fluctuates due to process variations. Note that the use of the Nch FET M1 enables suppression of the variation of the oscillation frequency even when the threshold voltage of the Nch FET fluctuates.

Note that, also in the circuit according to the first exemplary embodiment shown in FIG. 1, the variation of the oscillation frequency due to process variations in the Nch FET can be suppressed.

While the ring oscillator including the inverter circuits have been described by way of example in the first and second exemplary embodiments, the present invention is not limited thereto. It is also possible for other oscillation circuits having a configuration in which a time constant of a feedback loop circuit is determined by a resistance and a capacitance to adjust an oscillation frequency in a similar manner.

While the FETs constituting the correction circuits 100 and 200 have been described by way of example in the first and second exemplary embodiments, transistors to be employed are not limited thereto. Alternatively, various transistors such as a bipolar transistor may be employed.

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even when amended later during prosecution.

What is claimed is:

1. An oscillation circuit comprising:
a power supply voltage terminal applied with a power supply voltage;
a feedback loop circuit that outputs an oscillation frequency signal; and
a correction circuit that corrects a time constant of the feedback loop circuit in accordance with the power supply voltage applied to the power supply voltage terminal.

2. The oscillation circuit according to claim 1, wherein
the correction circuit comprises:
a capacitor element having one terminal connected to a node on the feedback loop circuit; and
a control circuit connected to each of the other terminal of the capacitor element and the power supply voltage terminal, and
the control circuit controls a resistance value between the other terminal of the capacitor element and a ground voltage terminal in accordance with the power supply voltage.

3. The oscillation circuit according to claim 2, wherein the control circuit comprises:
a resistor element connected between the power supply voltage terminal arid the ground voltage terminal;
a first transistor connected in series with the resistor element; and
a second transistor that is provided between the capacitor element and the ground voltage terminal, and is current-mirror connected to the first transistor.

4. An oscillation circuit according to claim 3, further comprising an additional circuit that is provided between the power supply voltage terminal and one terminal of the resistor element and that changes a correction factor of the time constant with respect to a fluctuation of the power supply voltage.

5. The oscillation circuit according to claim 4, wherein the additional circuit comprises a third transistor having a source terminal connected to the power supply voltage terminal, a drain terminal connected to the one terminal of the resistor element, and a gate terminal connected to the one terminal of the resistor element.

6. The oscillation circuit according to claim 3, wherein each of the first and second transistors comprises an N-channel MOS transistor

7. The oscillation circuit according to claim 3, wherein each of the first and second transistors comprises an NPN bipolar transistor.

8. The oscillation circuit according to claim 5 wherein the third transistor comprises a P-channel MOS transistor.
